(19) United States
(12) Patent Application Publication
(10) Pub. No.: US 2014/0065321 A1
(43) Pub. Date: Mar. 6, 2014

(54) PULL-BACK DESIGN TO MITIGATE PLASTIC SENSOR CRACKS

(71) Applicants: Wonsuk Chung, Los Altos, CA (US); Chun-Hao Tung, Tokyo (JP); Yu-Chun Tseng, Taipei (TW); Sunggu Kang, San Jose, CA (US); John Z. Zhong, Cupertino, CA (US); Siddharth Mohapatra, Santa Clara, CA (US)

(72) Inventors: Wonsuk Chung, Los Altos, CA (US); Chun-Hao Tung, Tokyo (JP); Yu-Chun Tseng, Taipei (TW); Sunggu Kang, San Jose, CA (US); John Z. Zhong, Cupertino, CA (US); Siddharth Mohapatra, Santa Clara, CA (US)

(73) Assignee: Apple Inc., Cupertino, CA (US)

(21) Appl. No.: 13/602,029

(22) Filed: Aug. 31, 2012

(51) Int. Cl. H05K 3/00

(52) U.S. Cl. 427/555; 427/99.2; 427/98.4; 118/35; 118/696; 118/697

(57) ABSTRACT

The described embodiments relate generally to the singulation of circuits and more particularly to a method of cutting of a polymer substrate that is overlaid with a conductive element and a passivation layer. In one embodiment, the passivation layer is applied selectively to the polymer substrate in an area covering the conductive element and extending at least a first distance past an outer edge of the conductive element. Then, a cutting operation is performed along a cutting path located a second distance from an outer edge of the passivation layer. The second distance is a minimum distance between the edge of the passivation layer and the cutting path that prevents a load applied at the second distance from causing a stress crack in the passivation layer.

### FIELD OF THE DESCRIBED EMBODIMENTS

The described embodiments relate generally to the singulation of circuits and more particularly to the cutting of a polymer substrate that is overlaid with a conductive element and a passivation layer.

### BACKGROUND

Polymer materials are commonly used in the construction of sensors for touchscreen displays and other types of electronic devices. Certain types of polymers can be useful as a substrate upon which sensors and other types of electronic circuitry are overlaid. Polymers can offer several advantages over other substrate materials such as glass due to their light weight and affordability.

Polymer substrates overlaid with electronic elements can be coated with a passivation layer to protect the conductive elements from being damaged. The passivation layer protects the conductive elements from wear damage as well as the corrosive effects of oxygen and moisture. Passivation layers can be applied to the polymer substrate in several ways, including dip-coating, spray-coating and printing. The common practice in the industry is to apply a uniform passivation layer to a roll or sheet of polymer material prior to cutting the material into the shape desired for the particular application. After a curing process, the passivation layer can become hard and brittle relative to the underlying materials.

After the passivation layer is applied and cured, the substrate can be cut into the desired form. Common methods of cutting include die-cutting, shearing, laser cutting, and mill cutting. During the cutting process, the brittleness of the cured passivation layer can lead to the formation of cracks along the cutting path. Subsequent manufacturing processes and handling of the device can cause these cracks to propagate through the passivation layer and into the polymer substrate. When this occurs, there is a risk that the crack could damage any conductive elements overlaid on the substrate, compromising the reliability of the device being manufactured.

Therefore, what is desired is method of cutting a polymer substrate that is overlaid with a conductive element and a passivation layer while minimizing the creation of cracks along the cutting path.

### SUMMARY OF THE DESCRIBED EMBODIMENTS

The present disclosure generally relates to a method for singulating a circuit by cutting a polymer substrate overlaid with a conductive element and a passivation layer. The creation of cracks along the cutting path can be minimized by selectively applying the passivation layer such that the edge of the passivation layer is set back from the cutting path. The polymer substrate is typically softer and less brittle than the overlying passivation layers. Therefore, the absence of the passivation layer along the cutting path can reduce the number of cracks created during the cutting process.

In one embodiment, a method of singulating a circuit is disclosed. The circuit can include a polymer substrate overlaid with at least one conductive element and a passivation layer. The method can include the following steps: (1) applying a passivation layer to a polymer substrate overlaid with a conductive element while allowing the passivation layer to extend at least a first distance past an outer edge of the conductive element; (2) identifying a cutting path at least a second distance from the outer edge of the passivation layer, where the second distance is a minimum distance between the edge of the passivation layer and the path that prevents a load applied at the second distance from creating a crack in the passivation layer; and (3) performing a cutting operation along the cutting path.

In another embodiment, a method of singulating a similar circuit by masking prior to applying a passivation layer and performing a cutting operation is disclosed. The method can include the following steps: (1) masking a region of a polymer substrate with a masking material such that an edge of the masking material maintains at least a first distance from the conductive element; (2) applying a passivation layer to the polymer substrate; (3) removing the masking material; (4) identifying a cutting path at least a second distance from an outer edge of the passivation layer, where the second distance is a minimum distance between the edge of the passivation layer and the cutting path that prevents a load applied at the second distance from creating a crack in the passivation layer; and (5) performing a cutting operation along the cutting path.

Other aspects and advantages of the disclosure will become apparent from the following detailed description taken in conjunction with the accompanying drawings which illustrate, by way of example, the principles of the described embodiments.

### BRIEF DESCRIPTION OF THE DRAWINGS

The described embodiments may be better understood by reference to the following description and the accompanying drawings. Additionally, advantages of the described embodiments may be better understood by reference to the following description and accompanying drawings. These drawings do not limit any changes in form and detail that may be made to the described embodiments. Any such changes do not depart from the spirit and scope of the described embodiments.

FIG. 1A shows a cross-sectional view of the conventional method for cutting a polymer substrate overlaid with a conductive element and a passivation layer.

FIG. 1B shows a plan view illustrating conventional methods for cutting a polymer substrate overlaid with a conductive element and a passivation layer.

FIG. 2 shows a cross-sectional view of a polymer substrate on which the passivation layer is set back, allowing the polymer substrate to be cut while minimizing the creation of cracks.

FIG. 3 shows how a conductive element and a passivation layer are arranged on a polymer substrate prior to the cutting operation.

FIG. 4 shows a plan view illustrating methods by which a passivation layer is selectively applied to a roll or sheet of polymer substrate material.

FIG. 5 shows a flow chart depicting the process for cutting a polymer substrate with a passivation layer utilizing a pattern or printing based method of applying the passivation layer.

FIG. 6 shows a flow chart depicting the process for cutting a polymer substrate with a passivation layer utilizing a masking process to restrict the application of the passivation layer.

FIG. 7 shows a system for applying a passivation layer to and cutting a polymer substrate, including a machine for applying a passivation layer, a machine for performing the cutting operation, and a controller.

FIG. 8 shows a block diagram of a controller suitable for use with the described embodiments.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

The electronics industry is creating an increasing number of devices with touchscreens and other types of visual displays. These devices can require a transparent substrate layer to provide structure for the screen and support for any included conductive elements for sensing touch inputs. Traditionally, the transparent substrate layer was made of glass but many devices are now being designed with polymer-based substrates due to their lighter weight and reduced cost. These new polymer-based materials can be received in roll or sheet form then cut into the required shape during the manufacturing process.

Prior to the cutting operation, the polymer substrate can be overlaid with touch capacitive circuitry. Typically, this includes a grid of indium-tin oxide or a similar transparent capacitive material. Once the touch capacitive circuitry is overlaid, the polymer substrate can be coated with a passivation layer to protect the conductive elements from wear damage and corrosion. The standard practice in the industry is to apply the passivation layer to the entire roll or sheet of substrate material prior to performing the cutting operation to create the desired shape. However, this method can lead to the formation of cracks in the passivation layer along the cutting path. The passivation layer that is formed over the substrate and capacitive material is typically harder and more brittle than the underlying polymer substrate. This can make the passivation layer more susceptible to fractures when placed under stress during the cutting process.

The formation of cracks in the passivation layer can create a risk of defects in the device being manufactured. While the cracks can be small at the time they are created by the cutting process, they have a tendency to propagate over time. Tensile and shear stresses imposed on the polymer substrate during both the manufacturing process and normal use of the device can cause stress concentrations at the tip of the cracks. These concentrations can cause the cracks to lengthen and enlarge over time. Given sufficient exposure to stress, the cracks can propagate through the passivation layer and into the polymer substrate.

The propagation of cracks beyond the passivation layer can cause several problems. First, cracks can cause damage to the conductive elements. The polymer substrate can support transparent conductive elements such as indium-tin oxide that make up the sensor of a touchscreen device. Thus, any cracks that permeate from the passivation layer to the underlying substrate can cause physical damage to the conductive elements and circuitry that lies between the substrate and passivation layer. Damage to these elements can result in defects and reliability issues in the device being manufactured. Second, cracks can compromise the structural integrity of the screen. Cracks can propagate deep into the polymer substrate layer if exposed to sufficient stress concentrations. This layer provides structural support for the screen. Thus, any significant defects can compromise the structural reliability of the device. Third, cracks in the passivation layer can allow contaminants such as moisture and oxygen to reach the conductive elements that overlay the polymer substrate. This can lead to corrosion of the conductive elements and ultimately defects in the device being manufactured. Finally, cracks can cause optical distortions. The polymer substrate is typically placed above an optical emitter such as an LED display. Therefore, it is advantageous that the polymer substrate and any additional layers be composed of materials that are transparent and do not distort the light being emitted from the display. A fracture in the polymer substrate caused by a crack in the passivation layer can inhibit the transmission of light through the cracked area, resulting in a visible distortion on the screen.

One solution to the previously described problems is to selectively apply the passivation layer to the polymer substrate prior to the cutting operation. The traditional manufacturing process includes application of the passivation layer to the entire roll or sheet of substrate material prior to the cutting operation. However, the passivation layer only needs to be applied to the areas in which conductive elements exist and the screen could be exposed to general wear and tear. Therefore, by limiting the application of the passivation layer to these regions, it is possible to avoid cutting the passivation layer during the cutting process. The polymer substrate is typically softer and less brittle than the passivation layer. Therefore, cracks are less likely to form when the polymer substrate layer is subjected to the cutting process without the addition of passivation layers.

There are several methods by which the passivation layer can be selectively applied to the polymer substrate. In one embodiment, the passivation layer is applied using a pattern or a printing process. An apparatus that selectively applies the passivation layer can be operated by hand or controlled by a computer for greater precision. Precise application of the passivation layer allows for smaller set-back distances to be attained between the edge of the passivation layer and the cutting path. In another embodiment, the areas of the polymer substrate on which the passivation layer is not necessary are masked prior to application of the passivation layer. This allows for less precise means of applying the passivation layer such as spray-coating and dip-coating. Once the passivation layer is applied, the masking material can be removed. Then, the cutting process can proceed in the areas where the masking material prevented the passivation layer from adhering to the polymer substrate. The absence of the passivation layer can reduce the occurrence of cracks along the cutting path.

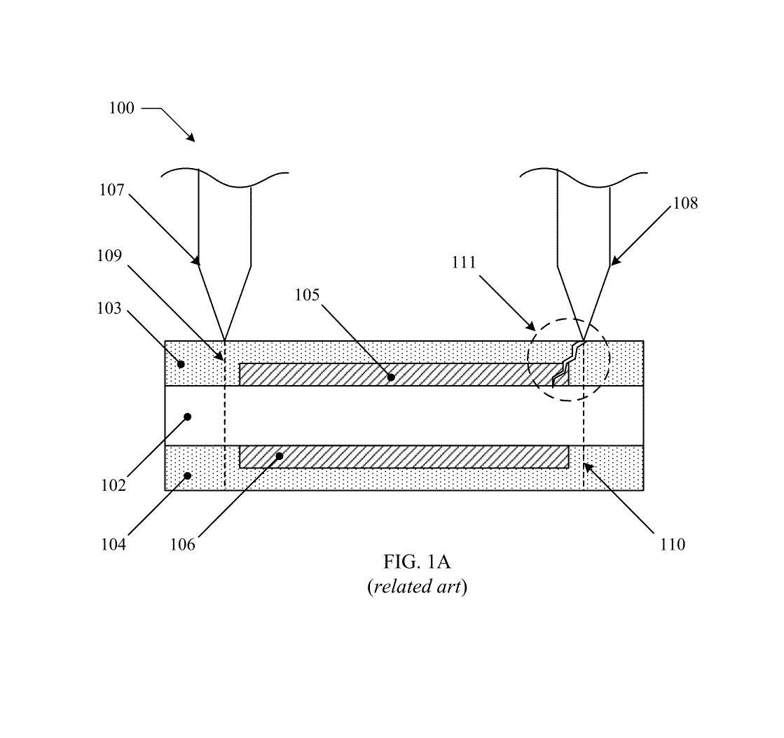

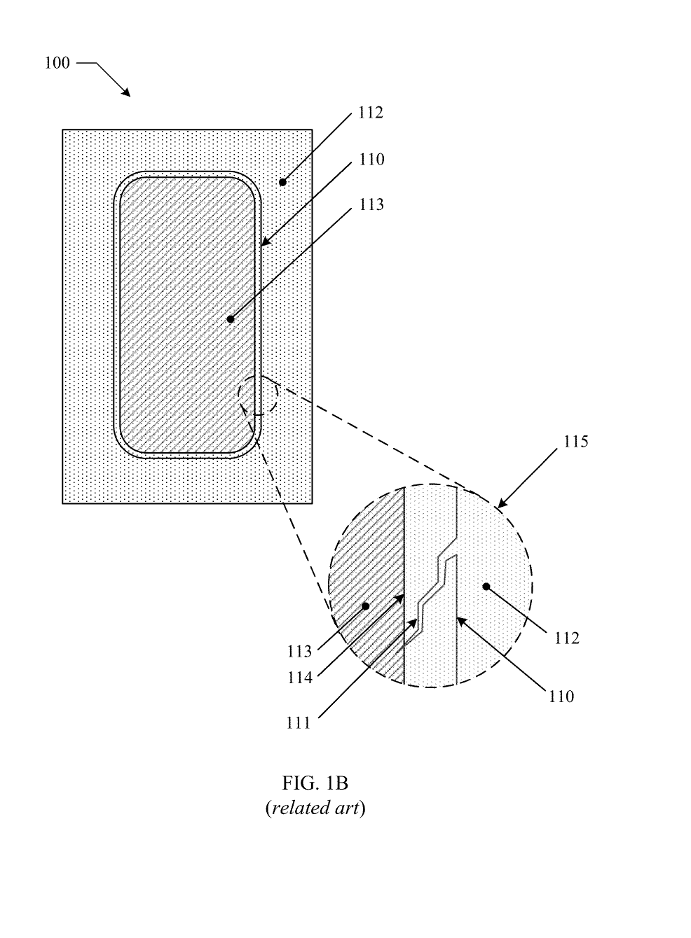

FIG. 1A shows a cross-sectional view of conventional method 100 for manufacturing and cutting a polymer substrate overlaid with conductive elements and passivation layers. Polymer substrate 102 can be overlaid on both sides by conductive elements 105 and 106. In addition, passivation layers 103 and 104 can overlay both substrate 102 and conductive elements 105 and 106. Using conventional manufacturing techniques, passivation layers 103 and 104 are often applied to an entire sheet or roll of polymer substrate 102 uniformly. After passivation layers 103 and 104 are applied, a curing process can be used to harden the passivation layers. Depending on the type of material used in the passivation layer, the curing process can involve applying heat, ultraviolet (UV) rays, or aging. After passivation layers 103 and 104 are cured, they can form a hard and brittle layer that is prone to fracturing when placed under stress. As a result of the uniform application of passivation layers 103 and 104, any cutting operation performed on polymer substrate 102 can include passivation layers 103 and 104 as well.

Cutters 107 and 108 are depicted cutting through passivation layers 103 and 104 and polymer substrate 102 along cutting paths 109 and 110. Cutters 107 and 108 can represent a die-cutter. However, many types of cutters can be used during the cutting operation, including but not limited to, shear cutters, rotary die-cutters, laser cutters, mill cutters, and water-jet cutters. Most types of cutters can create stress that can lead to fractures in passivation layers 103 and 104 and polymer substrate 102 along cutting paths 109 and 110. Thus, the disclosed method can be used regardless of the type of cutter employed. Crack 111 shows the typical way in which a fracture can form and propagate along the cutting path. Crack 111 can begin in passivation layer 103 due to the brittleness of the passivation material and can propagate through conductive element 105 and into polymer substrate 102. The passage of crack 111 through conductive element 105 can create a risk that an electrical connection within conductive element 105 could be severed, leading to an electrical defect in the in the device being manufactured. Moreover, crack 111 can allow corrosive materials such as moisture and oxygen to come into contact with conductive element 105 and could cause structural damage to polymer substrate 102.

FIG. 1B shows a plan view of conventional method 100 for manufacturing and cutting a polymer substrate overlaid with conductive elements and a passivation layer. Region 113 represents an area in which both conductive elements and a passivation layer are overlaid on the polymer substrate. Region 112 represents an area in which the polymer substrate is overlaid with a passivation layer. Cutting path 110 shows the path that the cutter follows when cutting the desired shape from a roll or sheet of polymer substrate material. Magnified view 115 shows a typical crack 111 that can form as a result of the conventional manufacturing method. Crack 111 initially forms along cutting path 110 and tends to propagate inward towards the interior of the cutout formed by cutting path 110. As crack 111 propagates inward, it can cross line 114, representing the edge of the region in which the polymer substrate is overlaid with conductive elements. As crack 111 propagates past line 114 and into region 113, there is a risk that the conductive elements in region 113 could be damaged.

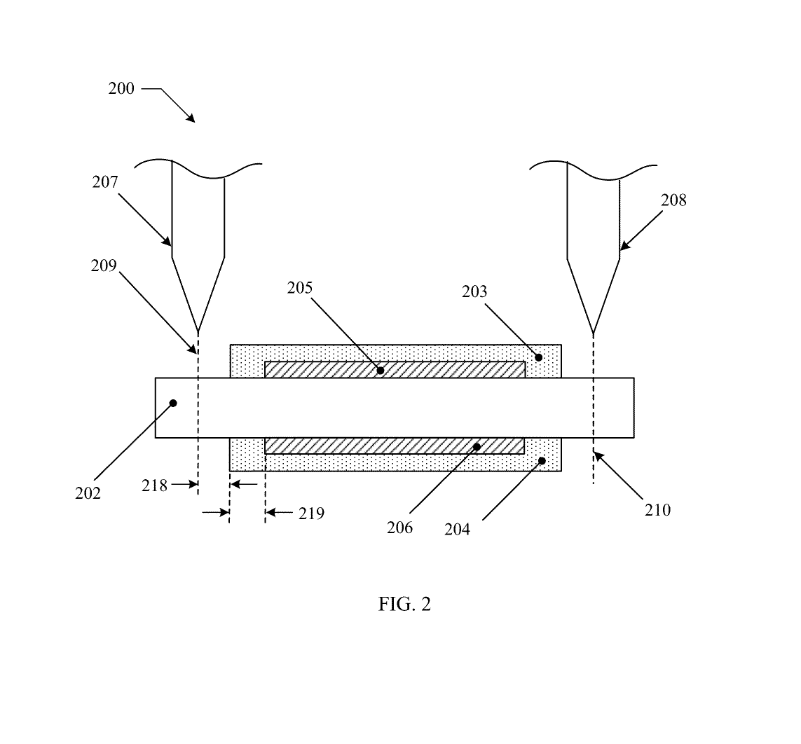

FIG. 2 shows a cross-sectional view of disclosed method 200 for manufacturing and cutting a polymer substrate that is overlaid with a conductive element and a passivation layer. Polymer substrate 202 can be overlaid on both sides by conductive elements 205 and 206. Polymer substrate 202 can be formed from many different polymer-based materials. Generally, for the construction of touchscreen sensors and other types of displays, it is desirable that the material be light weight, dimensionally stable, durable, and break and flex resistant. One class of materials that can meet these requirements is substrates formed from cyclic olefin polymers (COP). However, other materials such as unsaturated polyurethanes can be used as well. Thus, the present disclosure should not be limited to substrates constructed from COP. Conductive elements 205 and 206 can be overlaid on either side of polymer substrate 202. It is not necessary that conductive elements be overlaid on both sides of polymer substrate 202 and the present disclosure includes embodiments in which only conductive element 205 is present. When used in the construction of touchscreen sensors and displays, it can be advantageous that conductive elements 205 and 206 be made from material that is both conductive and transparent. The most commonly used material that meets these requirements is indium-tin oxide (ITO). However, other materials such as PEDOT:PSS and carbon nano-tubes can be used as well.

Passivation layers 203 and 204 are shown coating polymer substrate 102 and conductive elements 105 and 106. Passivation layers 203 and 204 can consist of any polymer-based passivation material. UV-cured polymer-based resins are commonly used as passivation materials, but other materials can be used as well. FIG. 2 depicts passivation layers 203 and 204 being applied on both sides of polymer substrate 202. However, it is not necessary to apply passivation layers to both sides of the substrate. Thus, the present disclosure includes embodiments in which only passivation layer 203 is present.

Cutters 207 and 208 are depicted cutting polymer substrate 202 along cutting paths 209 and 210. Cutters 207 and 208 can represent a die-cutter. However, many types of cutters can be used during the cutting operation, including but not limited to, rotary die-cutters, shear cutters, laser cutters, mill cutters, and water-jet cutters. Most types of cutters create stress that can lead to fractures in passivation layers 203 and 204 and polymer substrate 202 along cutting paths 209 and 210. Thus, the disclosed method can be used regardless of the type of cutter employed.

Unlike conventional manufacturing methods, the present disclosure shows passivation layers 203 and 204 set back from cutting paths 209 and 210. Passivation layer set-back distance 218 can be defined as the minimum allowable distance between the edge of passivation layers 203 and 204 and cutting paths 209 and 210. The precise value of passivation layer set-back distance 218 can vary according to the specific manufacturing process to which the disclosed method is being applied. However, it is advantageous for set-back distance 218 to be large enough that no inaccuracies in the application of the passivation layer or the cutting process can allow the cutter to come in contact with the passivation layer. For example, a value for passivation layer set-back distance 218 can be obtained by adding together the maximum allowable tolerance associated with the cutting process and the maximum allowable tolerance associated with the application of the passivation layer. It is not necessary that passivation layer set-back distance 218 be held constant along the cutting path and the present disclosure includes situations where the set-back distance is varied along different portions of the cutting path.

When conductive elements are placed between polymer substrate 202 and passivation layers 203 and 204, additional constraints on the application of passivation layers 203 and 204 can be needed. Conductive element set-back distance 219 can be defined as the minimum allowable distance between the edge of passivation layers 203 and 204 and the edge of conductive elements 205 and 206. The precise value of conductive element set-back distance 219 can vary according to the materials and manufacturing processes to which the disclosed method is being applied. However, it is advantageous for conductive element set-back distance 219 to be large enough to allow for adequate protection of the edges of conductive elements 205 and 206. For example, a conductive element set-back distance of 20 μm can be sufficient to protect the edges of conductive elements 205 and 206 from corrosion and wear damage in some circumstances. In addition, conductive element set-back distance 219 can account for any possible inaccuracies in the placement of conductive elements 205 and 206 and passivation layers 203 and 204. For example, a value for conductive element set-back distance 219 can be calculated by adding together the maximum allowable tolerance associated with the placement of the conductive elements, the maximum allowable tolerance associated with the application of the passivation layer, and a 20 μm overlap for the protection of the edges of conductive elements 205 and 206. It is not necessary that conductive element set-back distance 219 be held constant along the entire edge of passivation layers 203 and 204, and the present disclosure includes situations in which the set-back distance is varied along different portions of the passivation layer edge.

When passivation layer set-back distance 218 and conductive element set-back distance 219 are properly defined, cutters 207 and 208 can avoid coming into contact with passivation layers 203 and 204 during the cutting process. Polymer substrate 202 is typically softer and less brittle than passivation layers 203 and 204. Therefore, cracks can be less likely to form during the cutting process when the passivation layers are avoided.

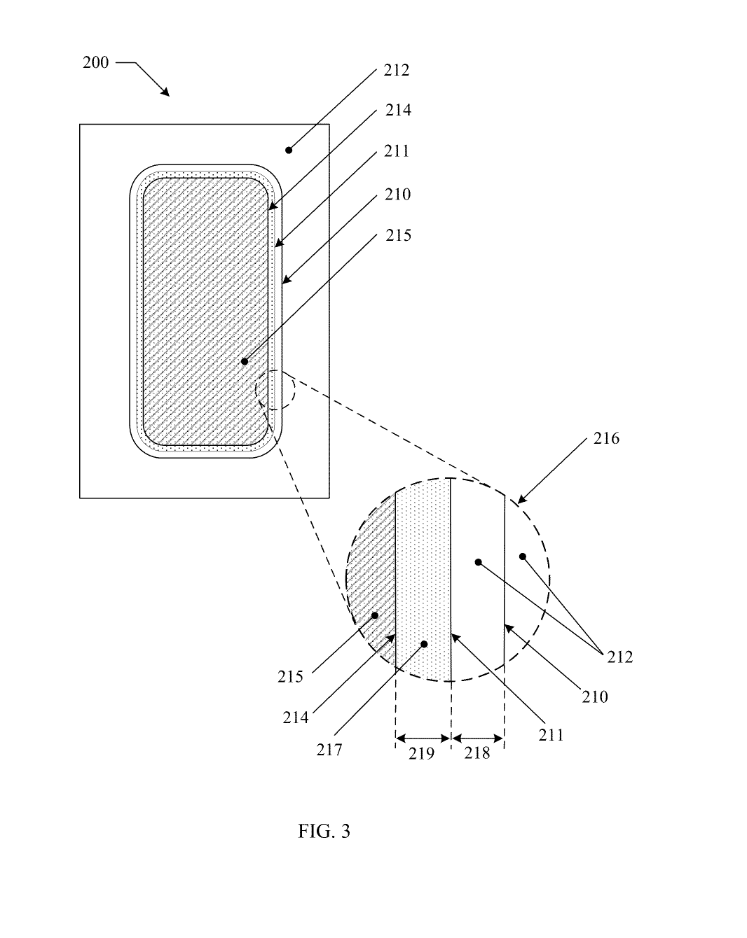

FIG. 3 shows a plan view of the disclosed method 200 for manufacturing and cutting a polymer substrate that is overlaid with a conductive element and a passivation layer. Region 212 shows an area in which no passivation layer is applied, region 217 shows an area in which the polymer substrate is overlaid with a passivation layer, and region 215 shows an area in which the polymer substrate is overlaid with both a conductive element and a passivation layer. Magnified view 216 depicts the manner in which the various layers can be arranged. In one embodiment, passivation layer set-back distance 218 can define the minimum allowable distance between cutting path 210 and passivation layer edge 211. Moreover, conductive element set-back distance 219 can define the minimum allowable distance between passivation layer edge 211 and conductive element edge 214. The application of the passivation layer to region 217 in accordance with set-back distances 218 and 219 can ensure that the passivation layer is positioned to avoid coming into contact with cutting path 210.

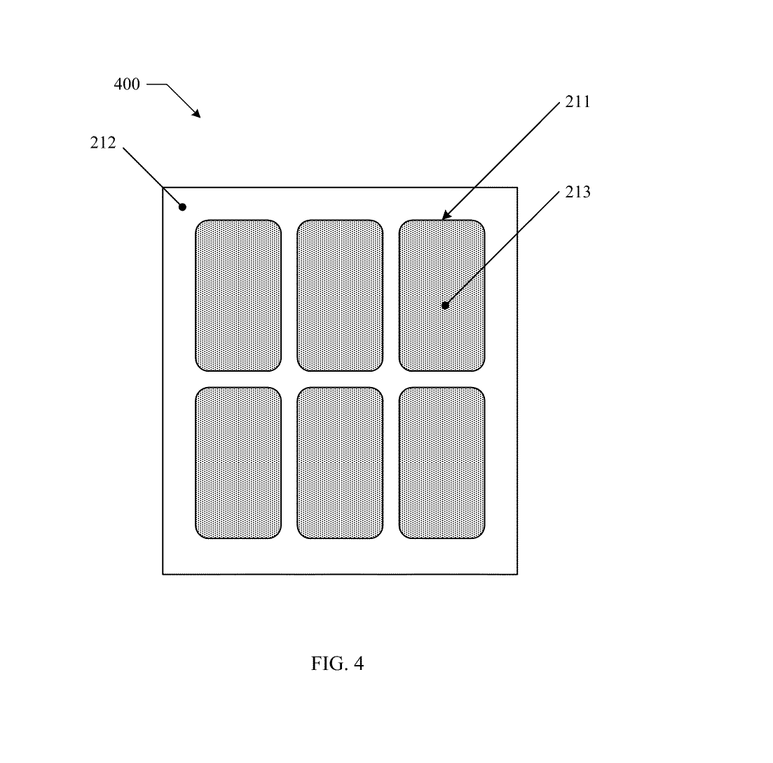

FIG. 4 shows a roll or sheet of polymer substrate material 400 after a passivation layer is applied and prior to the cutting process. Region 212 represents an area in which sheet 400 has not been treated with a passivation layer. Region 213 represents a typical area in which a passivation layer is applied to sheet 400. Edge 211 represents an edge of a typical region which has been coated with a passivation layer. In one embodiment, passivation layer 213 is applied to sheet 400 using an apparatus that employs a printing process or a pattern. In cases where polymer substrate sheet 400 is overlaid with conductive elements, it is advantageous that region 213 be sized and aligned to cover all conductive elements with an overlap greater than or equal to the conductive element set-back distance. In some cases, computer controlled equipment can be used to control the application of passivation layer 213 so that edge 211 is aligned with the appropriate degree of precision. In another embodiment, region 212 is covered with a masking material such that the edge of the masking material coincides with edge 211. Then, all or some of sheet 400 can be coated with a passivation layer using less precise means of application such as spray-coating or dip-coating. After the passivation layer is applied, the masking material in region 212 can be removed, limiting the passivation layer to region 213.

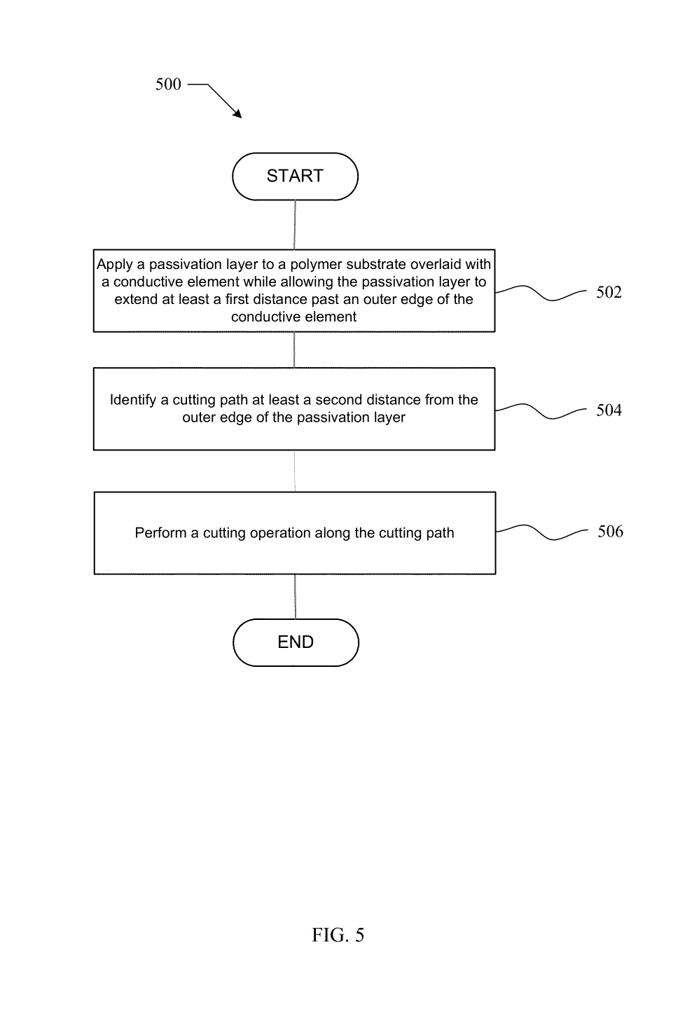

FIG. 5 shows a flow chart describing process 500 in accordance with the described embodiments. For example, process 500 can be appropriate when a pattern or printing process is used in the application of the passivation layer. In step 502, a passivation layer can be applied to a polymer substrate overlaid with a conductive element such that the passivation layer extends at least a first distance past an outer edge of the conductive element. The value of the first distance can be conductive element set-back distance 219 shown in FIG. 2. Proper alignment can allow the passivation layer to fully coat any conductive elements while avoiding the path of the cutter. In Step 504, a cutting path can be identified at least a second distance from an outer edge of the passivation layer. This second distance can be passivation layer set-back distance 218 shown in FIG. 2. Finally, in step 506, a cutting operation can be performed along the cutting path. In this way, the lack of passivation layer material along the cutting path can reduce the risk of fractures forming during the cutting operation.

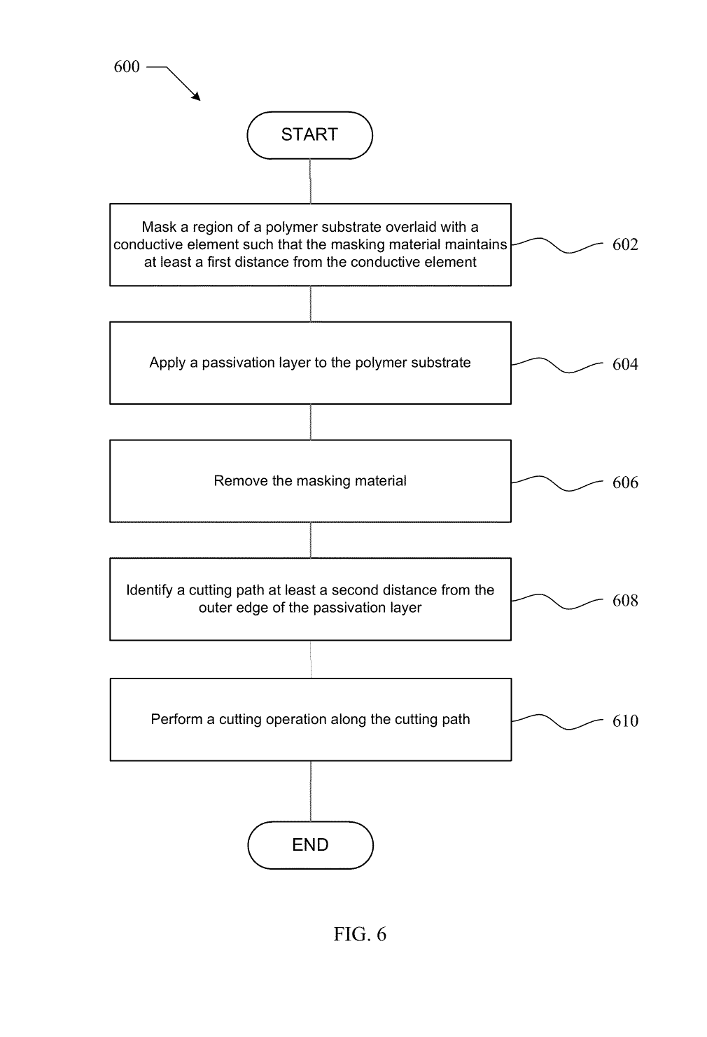

FIG. 6 shows a flow chart describing process 600 in accordance with the described embodiments. Process 600 can be appropriate when a masking process is used during the application of a passivation layer. In step 602, masking material can be applied to a predefined region of a polymer substrate overlaid with a conductive element such that the masking material maintains at least a first distance from the conductive element. The value of the first distance can be conductive element set-back distance 219 shown in FIG. 2. Next, in step 604, the polymer substrate can be coated with a passivation layer. The coating process can be carried out by less precise means than the process described in process 500 because the masking material prevents the passivation layer from adhering to the masked areas. After the passivation layer has been applied, step 606 can remove the masking material. In step 608 a cutting path can be identified at least a second distance from the outer edge of the passivation layer. This second distance can be passivation layer set-back distance 218 shown in FIG. 2. Finally, in step 610, a cutting operation can be performed along the cutting path. Once again, the lack of passivation layer material along the cutting path can reduce the risk of fractures forming during the cutting operation.

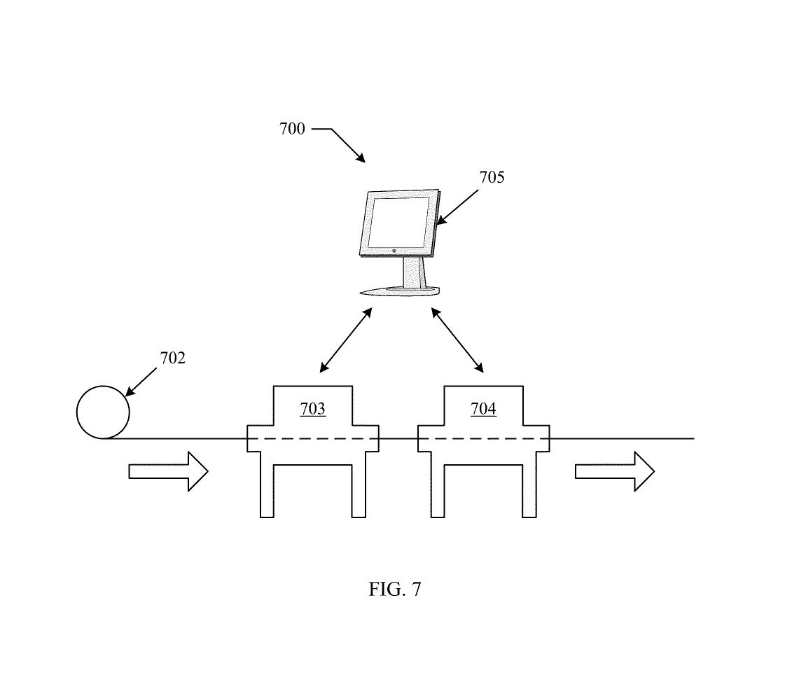

FIG. 7 shows system 700 for applying a passivation layer to and performing a cutting operation on a polymer substrate. Roll 702 can represent a roll of polymer substrate material. The polymer substrate can be overlaid with conductive elements. The roll of polymer substrate material can first be passed through passivation layer application machine 703. Machine 703 can apply the passivation layer selectively using a pattern or a printing process. Alternatively, machine 703 can utilize a masking process to selectively apply the passivation layer to the desired area. In addition, machine 703 can include a curing process. After passing through machine 703, the polymer substrate can pass through cutting machine 704. Machine 704 can cut the polymer substrate into the required shape. Machine 704 can represent a variety of different cutting machines, including but not limited to, die-cutters, rotary die-cutters, shear cutters, laser cutters, mill cutters, and water-jet cutters.

Both passivation layer application machine 703 and cutting machine 704 can be controlled by controller 705. Controller 705 can represent a single controller or multiple controllers working together. Controller 705 can include sensors in machines 703 and 704 to detect the location of any conductive elements overlaid on the polymer substrate. Once the location of any conductive elements is received, the controller can direct the operations of passivation layer application machine 703 to align the passivation layer with any conductive elements. This can allow conductive element set-back distance 219 (shown in FIG. 2) to be maintained. Furthermore, the controller can direct the operations of cutting machine 704 to align the cutting path with the conductive elements and the passivation layer. This can allow the cutting path to maintain passivation layer set-back distance 218 (shown in FIG. 2). In this manner, system 700 can prohibit the cutting path from intersecting the passivation layer, reducing the likelihood that fractures will form along the cutting path.

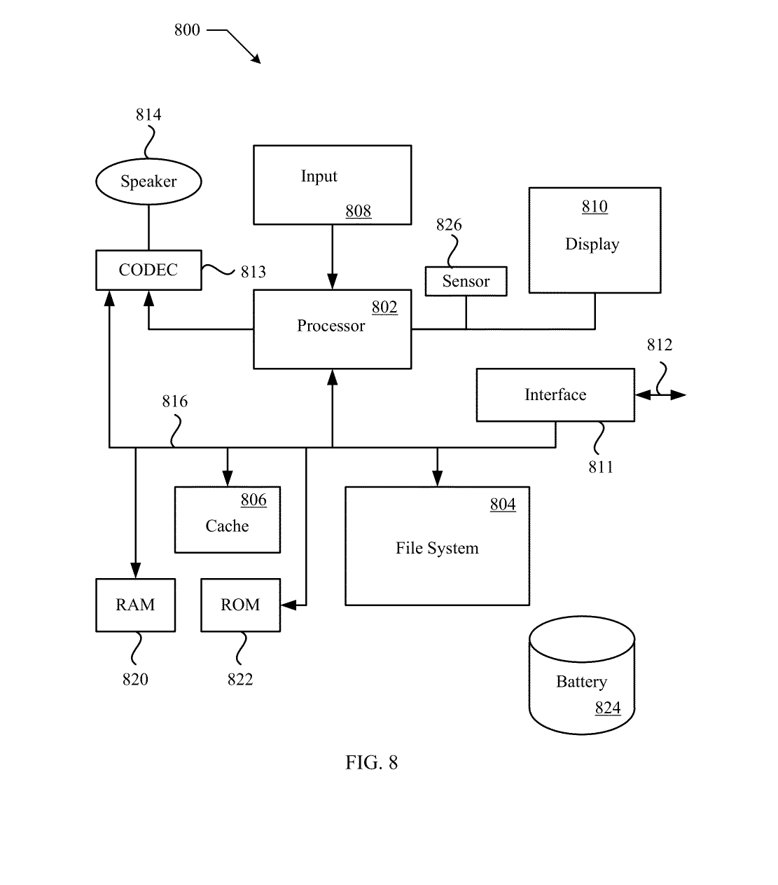

FIG. 8 is a block diagram of electronic controller 800 suitable for controlling some of the processes in the described embodiment. Controller 800 illustrates circuitry of a representative computing device. Controller 800 includes a processor 802 that pertains to a microprocessor or controller for controlling the overall operation of controller 800. Controller 800 contains instruction data pertaining to manufacturing instructions in a file system 804 and a cache 806. The file system 804 is, typically, a storage disk or a plurality of disks. The file system 804 typically provides high capacity storage capability for the controller 800. However, since the access time to the file system 804 is relatively slow, the controller 800 can also include a cache 806. The cache 806 is, for example, Random-Access Memory (RAM) provided by semiconductor memory. The relative access time to the cache 806 is substantially shorter than for the file system 804. However, the cache 806 does not have the large storage capacity of the file system 804. Further, the file system 804, when active, consumes more power than does the cache 806. The power consumption is often a concern when the controller 800 is a portable device that is powered by a battery 824. The controller 800 can also include a RAM 820 and a Read-Only Memory (ROM) 822. The ROM 822 can store programs, utilities or processes to be executed in a non-volatile manner. The RAM 820 provides volatile data storage, such as for cache 806.

The controller 800 also includes a user input device 808 that allows a user of the controller 800 to interact with the controller 800. For example, the user input device 808 can take a variety of forms, such as a button, keypad, dial, touch screen, audio input interface, visual/image capture input interface, input in the form of sensor data, etc. Still further, the controller 800 includes a display 810 (screen display) that can be controlled by the processor 802 to display information to the user. A data bus 816 can facilitate data transfer between at least the file system 804, the cache 806, the processor 802, and a CODEC 813. The CODEC 813 can be used to decode and play a plurality of media items from file system 804 that can correspond to certain activities taking place during a particular manufacturing process. The processor 802, upon a certain manufacturing event occurring, supplies the media data (e.g., audio file) for the particular media item to a coder/decoder (CODEC) 813. The CODEC 813 then produces analog output signals for a speaker 814. The speaker 814 can be a speaker internal or external to the controller 800. For example, headphones or earphones that connect to the controller 800 would be considered an external speaker.

The controller 800 also includes a network/bus interface 811 that couples to a data link 812. The data link 812 allows the controller 800 to couple to a host computer or to accessory devices. The data link 812 can be provided over a wired connection or a wireless connection. In the case of a wireless connection, the network/bus interface 811 can include a wireless transceiver. The media items can be any combination of audio, graphical or visual content. Sensor 826 can take the form of circuitry for detecting any number of stimuli. For example, sensor 826 can include any number of sensors for monitoring a manufacturing operation such as for example a Hall Effect sensor responsive to external magnetic field, an audio sensor, a light sensor such as a photometer, and so on.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A manufacturing method for singulating a circuit, comprising:
applying a passivation layer to the circuit, the circuit comprising a polymer substrate and a conductive element overlaying the polymer substrate, wherein the passivation layer extends at least a first distance past an outer edge of the conductive element;
identifying a path, the path being at least a second distance from the outer edge of the passivation layer, wherein the second distance is a minimum distance between the edge of the passivation layer and the path that prevents a load applied at the second distance from causing a stress crack in the passivation layer; and
singulating the circuit by cutting the polymer substrate along the identified path.

2. The method as recited in claim 1 wherein the first distance is at least 20 μm plus the maximum allowable tolerance associated with the application of the passivation layer.

3. The method as recited in claim 2 wherein the second distance is at least the sum of the maximum allowable tolerances associated with the cutting process and the application of the passivation layer.

4. The method as recited in claim 3 wherein the passivation layer is applied to the polymer substrate selectively using a printing process.

5. The method as recited in claim 3 wherein the passivation layer is applied to the polymer substrate selectively using a pattern.

6. The method as recited in claim 3 wherein applying the passivation layer to the circuit further comprises:
covering an area of the circuit with a masking material;
applying the passivation layer to the polymer substrate; and
removing the masking material.

7. The method as recited in claim 5 wherein the cutting operation is performed using a die-cutter.

8. The method as recited in claim 5 wherein the cutting operation is performed using a laser cutter.

9. The method as recited in claim 7 wherein the passivation layer is comprised of a UV-cured, polymer-based passivation material.

10. The method as recited in claim 9 wherein the polymer substrate is comprised of a plastic material.

11. The method as recited in claim 9 wherein the polymer substrate is comprised of a cyclic olefin polymer.

12. A system for applying a passivation layer to and cutting a polymer substrate overlaid with a conductive element, comprising:
means for applying a passivation layer to the circuit, the circuit comprising a polymer substrate and a conductive element overlaying the Polymer substrate, wherein the passivation layer extends at least a first distance past an outer edge of the conductive element;
means for identifying a path, the path being at least a second distance from the outer edge of the passivation layer, wherein the second distance is a minimum distance between the edge of the passivation layer and the path that prevents a load applied at the second distance from causing a stress crack in the passivation layer; and
means for singulating the circuit by cutting the polymer substrate along the identified path.

13. The system as recited in claim 12 wherein the first distance is at least 20 μm plus the maximum allowable tolerance associated with the application of the passivation layer.

14. The system as recited in claim 13 wherein the second distance is at least the sum of the maximum allowable tolerances associated with the cutting process and the application of the passivation layer.

15. The system as recited in claim 14 wherein the means for identifying the path comprises a computer and at least one sensor for determining the position of the conductive element.

16. The system as recited in claim 15 wherein the means for singulating the circuit comprises a die-cutter.

17. The system as recited in claim 16 wherein the means for applying the passivation layer utilizes a printing process.

18. The system as recited in claim 16 wherein the means for applying the passivation layer utilizes a pattern.

19. A non-transient computer readable medium for storing computer code executable by a processor in a computer aided manufacturing system for applying a passivation layer to and cutting a polymer substrate overlaid with a conductive element, comprising:
computer code for applying a passivation layer to the circuit, the circuit comprising a polymer substrate and a conductive element overlaying the polymer substrate, wherein the passivation layer extends at least a first distance past an outer edge of the conductive element;
computer code for identifying a path, the path being at least a second distance from the outer edge of the passivation layer, wherein the second distance is a minimum distance between the edge of the passivation layer and the path that prevents a load applied at the second distance from causing a stress crack in the passivation layer; and
computer code for singulating the circuit by cutting the polymer substrate along the identified path.

20. The non-transient computer readable medium as recited in claim 19, wherein the first distance is at least 20 μm plus the maximum allowable tolerance associated with the application of the passivation layer.

21. The non-transient computer readable medium as recited in claim 20, wherein the second distance is at least the sum of the maximum allowable tolerances associated with the cutting process and the application of the passivation layer.
